(19) United States
(12) Patent Application Publication
(10) Pub. No.: US 2026/0150314 A1
(43) Pub. Date: May 28, 2026

(54) DEFECT FREE BIPOLAR TRANSISTOR

(71) Applicant: GlobalFoundries Singapore Pte. Ltd., Singapore (SG)

(72) Inventors: Seow Wei Lai, Singapore (SG); Hao Nong, Singapore (SG); Xinshu Cai, Singapore (SG); Kien Seen Daniel Chong, Singapore (SG); Boon Pin Teoh, Singapore (SG); Vibhor Jain, Clifton Park, NY (US)

(21) Appl. No.: 18/962,168

(22) Filed: Nov. 27, 2024

(51) Int. Cl. H10D 10/40; H01L 21/768; H10D 10/01; H10D 62/13; H10D 62/17; H10D 62/83

(52) U.S. Cl. CPC H10D 10/40; H10D 10/051; H10D 62/133; H10D 62/177; H10D 62/83; H10W 20/056

(57) ABSTRACT

The present disclosure relates to semiconductor structures and, more particularly, to a defect free bipolar transistor and methods of manufacture. The structure includes: a collector region; an emitter region over the base region; and an extrinsic base region adjacent to the emitter region, the extrinsic base region comprising a raised wing extension at a perimeter thereof.

### BACKGROUND

The present disclosure relates to semiconductor structures and, more particularly, to a defect free bipolar transistor and methods of manufacture.

A bipolar transistor is a type of transistor which includes a pn junction between two semiconductor types in a single crystal semiconductor material, i.e., n-type or p-type. Accordingly, a bipolar transistor can be either a npn transistor or a pnp transistor based on the type of junction. Bipolar transistors are used for amplification of signals, switching, and in mixed-signal integrated circuits using BiCMOS. For example, the bipolar transistor can be used for high voltage switches, radio-frequency (RF) amplifiers, or for switching high currents.

### SUMMARY

In an aspect of the disclosure, a structure comprises: a collector region; an emitter region over the base region; and an extrinsic base region adjacent to the emitter region, the extrinsic base region comprising a raised wing extension at a perimeter thereof.

In an aspect of the disclosure, a structure comprises: a collector region within a semiconductor substrate; an emitter region over the base region; a patterned stack of materials over the semiconductor substrate; and an extrinsic base region adjacent to the emitter region and adjacent to the patterned stack of materials, the extrinsic base region comprising a wing extension extending on a top surface of the patterned stack of materials.

In an aspect of the disclosure, a method comprises: forming a collector region; forming an emitter region over the base region; and forming an extrinsic base region adjacent to the emitter region, the extrinsic base region comprising a raised wing extension at a perimeter thereof.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIG. 2 shows the structure of FIG. 1 integrated with a BiCMOS device in accordance with aspects of the present disclosure.

FIGS. 3A-3D show respective fabrication processes for fabricating the structure of FIG. 1 in accordance with aspects of the present disclosure.

### DETAILED DESCRIPTION

The present disclosure relates to semiconductor structures and, more particularly, to a defect free bipolar transistor and methods of manufacture. More specifically, the defect free bipolar transistor may be a PNP device integrated into a BiCMOS device. In embodiments, the BiCMOS device may be a SiGe BiCMOS device. Advantageously, the present disclosure provides a 100% rail defect reduction at no additional fabrication cost or throughput impact.

In more specific embodiments, the bipolar device comprises a raised extrinsic base surrounding an emitter region. In embodiments, the raised extrinsic base comprises a wing-like extension (e.g., winglet) along an outer perimeter, overlapping dielectric material and a semiconductor layer. The winglet, dielectric material (e.g., dielectric stack of materials) and the semiconductor layer may be provided over a shallow trench isolation region. The emitter region and the base region may also be on a same level. The device may include multiple emitter regions and a central base contact between the emitter regions and, e.g., between the winglets. Advantageously, the fabrication processes and final structure eliminate rail defects. As should be known in the art, rail defects are residual polysilicon material resulting from the fabrication of the extrinsic base regions and emitter regions of a conventional device. The rail defects may result in shorting of the device or performance degradation.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

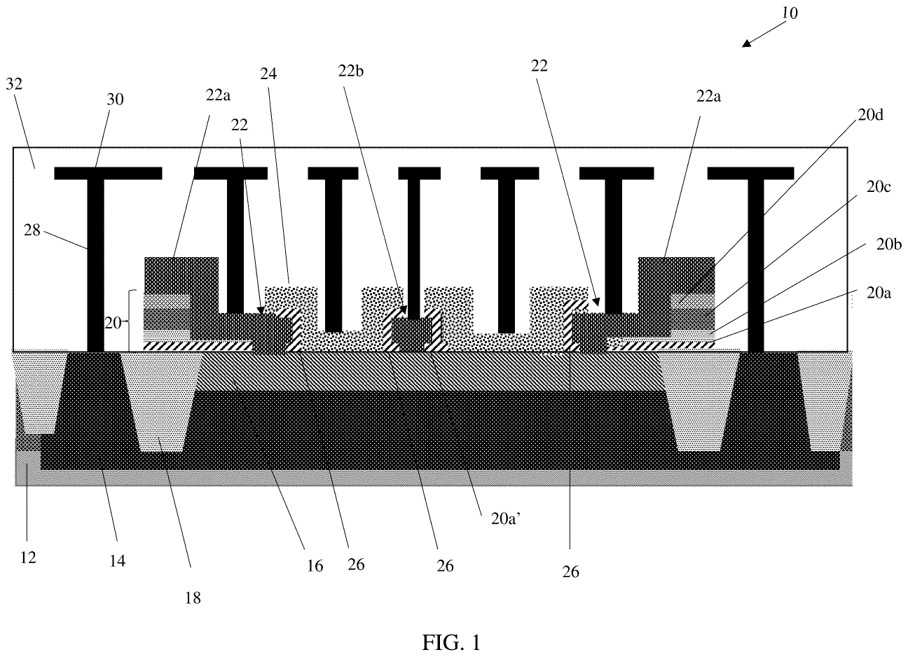

FIG. 1 shows a structure and respective fabrication processes in accordance with aspects of the present disclosure. In embodiments, the structure 10 includes a semiconductor substrate 12 composed of any suitable material including, but not limited to, Si, SiGe, SiGeC, SiC, alloys, GaAs, InAs, InP, and other III/V or II/VI compound semiconductors. In preferred embodiments, the semiconductor substrate 12 may comprise Si with a single crystalline orientation, e.g., any suitable crystallographic orientation (e.g., a (100), (110), (111), or (001) crystallographic orientation). The semiconductor substrate 12 may be a p-type substrate.

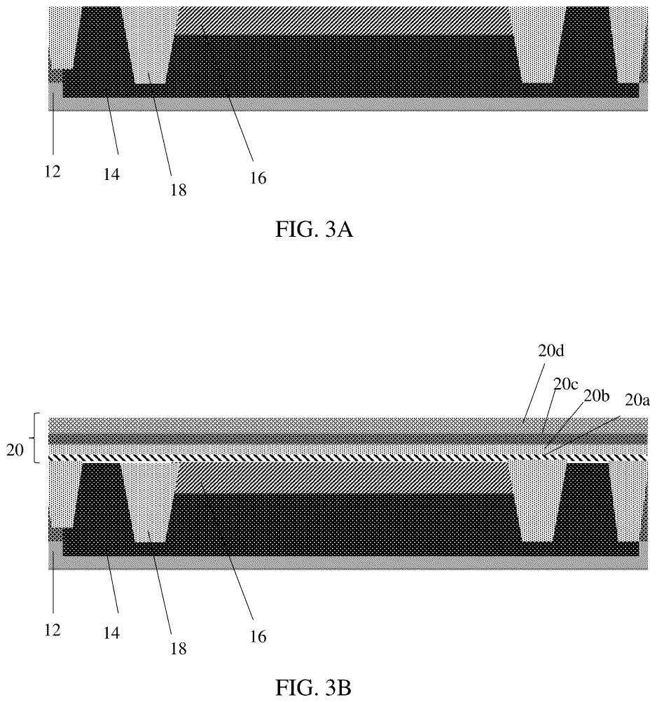

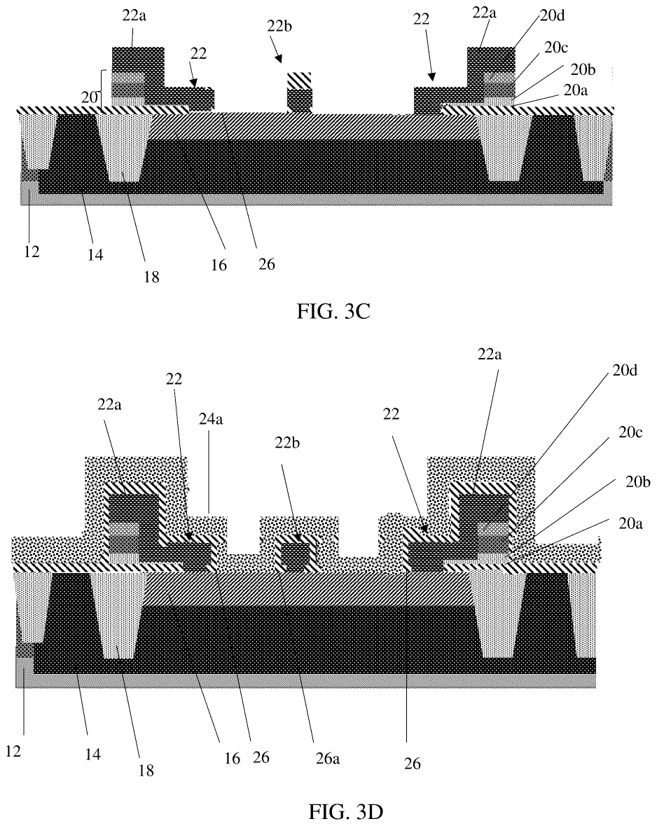

As further shown in FIG. 1, the semiconductor substrate 12 may include a collector region 14 and an intrinsic base region 16. In embodiments, the collector region 14 may be a p-well formed by conventional ion implantation processes as described with respect to FIG. 3A. The intrinsic base region 16 may be formed in the collector region 14, e.g., p-well. The intrinsic base region 16 may be an n-well formed from an ion implantation process as described with respect to FIG. 3A.

FIG. 1 further shows shallow trench isolation structures 18 extending between the collector region 14 and the intrinsic base region 16, in addition to isolating the collector region 14 from remaining portions of the semiconductor substrate 12. The shallow trench isolation structures 18 can be formed by conventional lithography, etching and deposition methods known to those of skill in the art and as described with respect to FIG. 3A.

FIG. 1 further shows a stack of materials 20 formed on the semiconductor substrate 12. In embodiments, the stack of materials 20 may include dielectric materials 20a, 20b and semiconductor materials 20c, 20d. In embodiments, the dielectric material 20a may be a nitride material and the dielectric material 20b may be an oxide material, e.g., TEOS (Tetraethyl orthosilicate). Further, the semiconductor materials 20c, 20d may include, for example, SiGe and Si, respectively. In embodiments, the Si material may be epitaxially grown on the SiGe material as is known in the art. Also, as shown in FIG. 1 and described in more detail with respect to FIG. 3C, the stack of materials 20 may be patterned to accommodate the extrinsic base region 22, 22b and the emitter regions 24. The patterning results in the stack of materials 20 formed partially or fully over the inner shallow trench isolation structures 18.

As further shown in FIG. 1, the extrinsic base region 22, 22b may be a raised extrinsic base region and a central base region, respectively, formed by conventional epitaxial growth processes or conventional deposition processes, followed by a patterning process. The extrinsic base region 22b may be a central extrinsic base region surrounded by the emitter regions 24 and the extrinsic base region 22. The patterning process will reduce any rail defects. As should be known in the art, rail defects are residual polysilicon material that results from the fabrication the extrinsic base regions.

The extrinsic base region 22 may be formed over the patterned stack of materials 20 (including the dielectric materials and semiconductor material) and the inner shallow trench isolation structures 18. In more specific embodiments, the extrinsic base region 22 may be formed over the patterned stack of materials 20 fully or partially over the inner shallow trench isolation structures 18. In embodiments, for example, the extrinsic base region 22 may be formed over a top surface of the dielectric material 20a, sides of the materials 20a, 20b, 20c, 20d and on a top surface of the semiconductor material 20b (e.g., forming wing-like extensions 22a). Moreover, the extrinsic base regions 22, 22b may further contact the underlying intrinsic base region 16, with the extrinsic base region 22, 22b provided partially over a top surface of the dielectric material 20a and partially over the intrinsic base region 16. Also, the extrinsic base region 22b may be a central extrinsic base region formed surrounded by the emitter regions 24.

In embodiments, the extrinsic base regions 22, 22b and wing-like extensions 22a may comprise a polysilicon material that is deposited by a conventional deposition method, e.g., chemical vapor deposition (CVD), followed by a patterning process as further described in FIG. 3C. In embodiments, the polysilicon material may be n-doped polysilicon material. The patterning process may be a conventional lithography and etching (RIE) processes as is known in the art, which will expose portions of the underlying intrinsic base region 16 for subsequent formation of the emitter regions 24, between the wing-like structures 22a and surrounding the central extrinsic base region 22b. The patterning process may also form the wing-like extensions 22a on an outer perimeter thereof and over the stack of materials 20, effectively eliminating rail defects which would otherwise be present adjacent to the stack of material 20 in conventional devices. Also, the emitters 24, the extrinsic base region 22, 22b and intrinsic base region 16 and the collector region 14 form an PNP device.

Sidewall spacers 26 may be formed on sidewalls of the extrinsic base regions 22, 22b. In embodiments, the sidewalls spacers 26 may be formed after the patterning process of the extrinsic base regions 22, 22a, 22b. The sidewall spacers 26 may be an oxide material, nitride material or combination thereof. The sidewall spacers 26 may be formed by a conventional deposition process, e.g., CVD, followed by an etching process with polysilicon material used to form the emitter regions 24. In alternative embodiments, unwanted sidewall material may be etched away (e.g., removed) prior to the formation of the emitter regions 24. In embodiments, the sidewall spacers 26 may isolate the extrinsic base region 22, 22b from the emitter region 24.

The emitter regions 24 may be formed by deposition of a polysilicon material on the intrinsic base region 16 and the extrinsic base regions 22, 22b as described with respect to FIG. 3D. In more specific embodiments, the emitter regions 24 may be formed by deposition of a polysilicon material on the insulator of the sidewall spacers 26. The polysilicon material may be p-doped polysilicon (e.g., Boron doped). The polysilicon material of the emitter regions 24 will surround the extrinsic base region 22b and will be surrounded by the base regions 22, e.g., wing-like extensions 22a (e.g., winglets). That is, the emitter regions 24 may be surrounded by the extrinsic base region 22b with the wing-like extensions 22a; whereas the emitter regions 24 may be surrounded by the extrinsic base region 22. The emitter regions 24 may be isolated from the base regions 22, 22b by the sidewall spacer material of the sidewall spacers 26. The emitter regions 24 may be patterned by conventional lithography and etching (RIE) processes. In embodiments, the etching process may also include etching the material of the sidewall spacer material to expose the base regions 22, 22b.

Contacts 28 and wiring structures 30 may be formed in contact with the collector region 14, the base regions 22, 22b and the emitter regions 24. The contacts 26 and wiring structures 30 may be formed by conventional lithography, etching and deposition processes as is known in the art and further described herein. Prior to the formation of the contacts 28 and wiring structures 30, the exposed semiconductor material of the collector region 14, the base regions 22, 22b and the emitter regions 24 may undergo a silicide process.

As should be understood by those of skill in the art, the silicide process begins with deposition of a thin transition metal layer, e.g., nickel, cobalt or titanium, over fully formed and patterned semiconductor devices (e.g., collector region 14, base regions 22, 22b and emitter regions 24). After deposition of the material, the structure is heated allowing the transition metal to react with exposed silicon (or other semiconductor material as described herein) forming a low-resistance transition metal silicide. Following the reaction, any remaining transition metal is removed by chemical etching, leaving silicide contacts in the active regions of the device.

The contacts 28 (e.g., interlevel contact vias) and wiring structures 30 may be formed within interlevel dielectric material 32. In embodiments, the interlevel dielectric material 32 may be, for example, oxide, nitride or combinations of layers thereof. The interlevel dielectric material 30 may be formed by conventional deposition methods, e.g., CVD, followed by a conventional chemical mechanical planarization (CMP) process.

The contacts 28 and wiring structures 30 may be formed by patterning the interlevel dielectric material 32 to expose the underlying silicide contacts on the collector region 14, base regions 22, 22b and emitter regions 24. By way of examples, the contacts 26 and wiring structures 28 may be formed by two separate single damascene processes or a dual damascene process. In either process configuration, conductive material will be deposited within the trenches (formed by the patterning processes) to form the contacts 28 and wiring strictures 30. The conductive material of the contacts 28 may be, for example, tungsten with a TiN or TaN liner. The conductive material for the wiring structures 30 may be aluminum or copper or other conductive materials known to those of ordinary skill in the art such that no further explanation is required for a complete understanding of the present disclosure. Any excessive conductive material on the interlevel dielectric material 32 may be removed by conventional CMP processes.

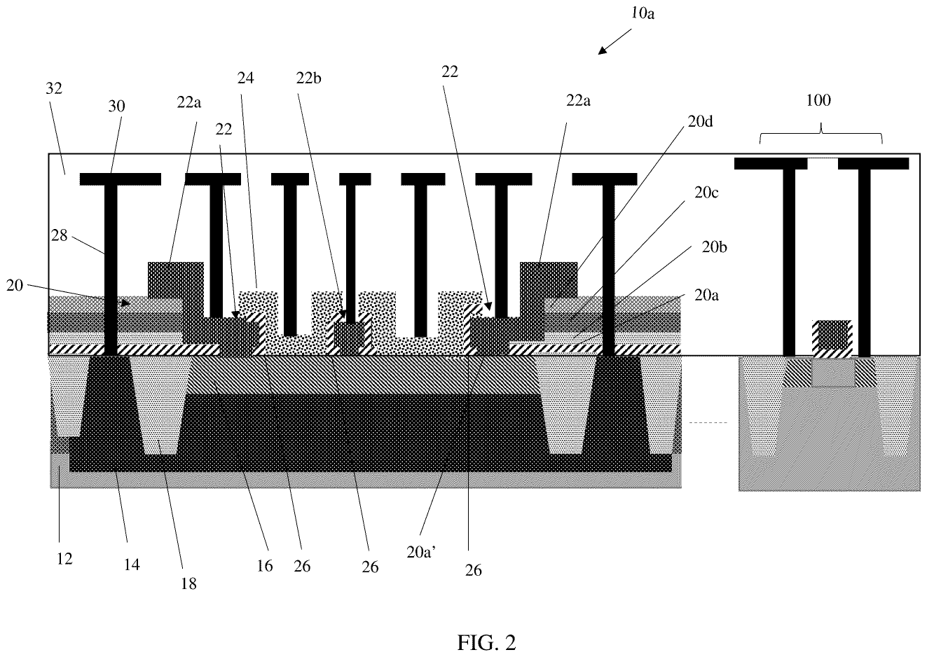

FIG. 2 shows the structure of FIG. 1 integrated with a BiCMOS device in accordance with aspects of the present disclosure. More specifically, the structure 10a includes a BiCMOS device 100 on a same semiconductor substrate 12 as the structure (e.g., PNP device) 10 of FIG. 1. In embodiments, the BiCMOS device 100 may include a gate structure comprising a gate dielectric material and a gate electrode, with sidewall spacers. The gate dielectric material may be a low-k or high-k dielectric material. The low-k dielectric material may be a gate oxide; whereas the high-k dielectric material may be hafnium based materials. The gate electrode may be polysilicon material and the sidewall spacers may be oxide or nitride or combinations thereof.

Diffusion regions, e.g., source and drain regions, may be provided on sides of the gate structure. The diffusion regions may be formed by conventional ion implantation processes as described herein (together or separately from the collector region 14 and/or intrinsic base region 16). The gate structure may be formed by conventional deposition and patterning processes as already described herein, wherein many of the processes used for the formation of the emitter regions and/or extrinsic base regions may be used to form the gate structures. The contacts 28 and wiring structures 30 to the gate structure and diffusion regions may be formed with the contacts 28 and wiring structures 30 as shown in FIG. 1.

FIGS. 3A-3D show respective fabrication processes for fabricating the structure of FIG. 1 in accordance with aspects of the present disclosure. FIG. 3A shows the formation of the collector region 14 and the intrinsic base region 16, amongst other features. In particular, in FIG. 3A, the collector region 14 and the intrinsic base region 16 may be formed by separate ion implantation processes. For example, the collector region 14 may be formed by introducing a p-type dopant into the semiconductor substructure 12 and the intrinsic base region 16 may be formed by introducing an n-type dopant into the semiconductor substructure 12.

In embodiments, the ion implantation processes includes using a patterned implantation mask used to define selected areas exposed for the implantation. The implantation mask may include a layer of a light-sensitive material, such as an organic photoresist, applied by a spin coating process, pre-baked, exposed to light projected through a photomask, baked after exposure, and developed with a chemical developer. The implantation mask has a thickness and stopping power sufficient to block masked areas against receiving a dose of the implanted ions. The p-type dopants may be, e.g., Boron (B); whereas, the n-type dopants may be, e.g., Arsenic (As), Phosphorus (P) and Antimony (Sb), among other suitable examples.

FIG. 3A further shows the formation of the shallow trench isolation structures 18. The shallow trench isolation structures 18 may be formed by conventional lithography, etching and deposition processes. For example, a resist formed over the semiconductor substrate 12 is exposed to energy (light) and developed utilizing a conventional resist developer to form a pattern (opening). An etching process with a selective chemistry, e.g., reactive ion etching (RIE), will be used to transfer the pattern from the photoresist layer to the semiconductor substrate 12 to form one or more trenches in the semiconductor substrate 12 through the openings of the resist. Following the resist removal by a conventional oxygen ashing process or other known stripants, insulator material (e.g., oxide based material) can be deposited by any conventional deposition processes, e.g., chemical vapor deposition (CVD) processes. Any residual material on the surface of the semiconductor substrate 12 can be removed by conventional chemical mechanical polishing (CMP) processes.

FIG. 3B shows the formation of the stack of materials 20 over the semiconductor substrate 12. The stack of materials 20 includes dielectric materials 20a, 20b and semiconductor materials 20c, 20d. The dielectric material 20a may be a nitride material formed by a conventional deposition process, e.g. CVD. The dielectric material 20b may be an oxide material. In embodiments, the oxide material may be, e.g., TEOS (Tetraethyl orthosilicate). The semiconductor material 20c may be SiGe, which is deposited by a conventional deposition method, e.g., CVD. The semiconductor material 20d may be Si material epitaxially grown on the SiGe material as is known in the art.

Examples of various epitaxial growth process apparatuses that can be employed in the present disclosure include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth may be performed at a temperature of from 300° C. to 800° C. The epitaxial growth can be performed utilizing any well-known precursor gas or gas mixture. Carrier gases like hydrogen, nitrogen, helium and argon can be used. A dopant (n-type or p-type as defined below) is typically added to the precursor gas or gas mixture.

In FIG. 3C, the stack of materials 20 may be patterned to expose the underlying semiconductor substrate 12. The patterning may result in a stepped feature of the stack of materials 20, where some dielectric material 20a remaining on the semiconductor substrate 12 without any remaining materials on top of the dielectric material 20a. The patterning process may be conventional lithography and etching processes as is known in the art, which results in the patterned stack of materials 20 partially or fully over shallow trench isolation structures 18.

FIG. 3C further shows polysilicon material formed over the patterned stack of materials 20. In embodiments, the polysilicon material may be p-doped polysilicon material formed by an epitaxial growth process with an in-situ n-type dopant. The polysilicon material may be patterned to form the extrinsic base region 22, 22b and the wing-like extension 22a over the patterned stack of materials 20 and the shallow trench isolation structure 18. This patterning expose the underlying semiconductor substrate 12 and will also eliminate any rail defects that would otherwise form from the patterning of the polysilicon material during fabrication of conventional devices.

In FIG. 3D, the sidewall spacer material 26 may be deposited over patterned polysilicon material which forms the extrinsic base region 22, 22b and the wing-like extension 22a. The sidewall spacer material 26a may also be deposited over exposed portions of the semiconductor substrate 12 and the patterned stack of materials 20. Polysilicon material 24a may be formed over the sidewall spacer material 26a. The polysilicon material 24a may be p-doped polysilicon material which is patterned to form the emitter regions 24.

As described with respect to FIG. 1, the polysilicon material 24a and the sidewall spacer material 26a may be patterned to form the emitter regions 20 and the sidewall spacers 26. The patterning process will expose the polysilicon material of the extrinsic base region 22, 22b and the collector region 12. The exposed polysilicon material of the extrinsic base region 22, 22b and the semiconductor material of the collector region 12 will undergo a silicide process, followed by deposition of the interlevel dielectric material 32. The remaining back end of the line processes, e.g., forming of the contacts 28 and wiring structures 30 are further described using conventional lithography, etching and deposition processes as already described herein such that no further explanation is required for a complete understanding of the present invention.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a collector region;
an emitter region over the base region; and
an extrinsic base region adjacent to the emitter region, the extrinsic base region comprising a raised wing extension at a perimeter thereof.

2. The structure of claim 1, wherein the raised wing extension is over a shallow trench isolation structure.

3. The structure of claim 1, wherein the raised wing extension is above a stack of materials.

4. The structure of claim 3, wherein the stack of materials comprises dielectric materials and semiconductor materials.

5. The structure of claim 4, wherein the raised wing extension sits on Si material.

6. The structure of claim 1, wherein the emitter region is surrounded by the raised wing extension.

7. The structure of claim 6, wherein the raised wing extensions are on an outer perimeter of the extrinsic base region.

8. The structure of claim 1, wherein the extrinsic base region comprises a central extrinsic base region.

9. The structure of claim 8, wherein the emitter region comprises multiple emitters.

10. The structure of claim 8, wherein the central extrinsic base region is surrounded by the raised wing extensions of the extrinsic base region.

11. The structure of claim 8, wherein the central extrinsic base region is surrounded by the emitter region.

12. The structure of claim 1, wherein the structure comprises a bipolar device and further comprising a BiCMOS device integrated with the bipolar device on a same semiconductor substrate.

13. A structure comprising:
a collector region within a semiconductor substrate;
an emitter region over the base region;
a patterned stack of materials over the semiconductor substrate; and
an extrinsic base region adjacent to the emitter region and adjacent to the patterned stack of materials, the extrinsic base region comprising a wing extension on a top surface of the patterned stack of materials.

14. The structure of claim 13, further comprising shallow trench isolation structures within the semiconductor substrate, wherein the wing extension and the patterned stack of materials are at least partially over the shallow trench isolation structures.

15. The structure of claim 13, wherein the wing extension is a raised wing extension at an outer perimeter of the extrinsic base region.

16. The structure of claim 15, wherein the emitter region is surrounded by the raised wing extension.

17. The structure of claim 13, wherein the extrinsic base region comprises a central extrinsic base region which is surrounded by the emitter region.

18. The structure of claim 17, wherein the emitter region comprises multiple emitters.

19. The structure of claim 13, wherein the patterned stack of materials comprises semiconductor materials over dielectric materials.

20. A method comprising:
forming a collector region;
forming an emitter region over the base region; and
forming an extrinsic base region adjacent to the emitter region, the extrinsic base region comprising a raised wing extension at a perimeter thereof.
